(19) United States
(12) Patent Application Publication
(10) Pub. No.: US 2012/0003485 A1
(43) Pub. Date: Jan. 5, 2012

(54) Monolayers of organic compounds on metal oxide surfaces or metal surfaces containing oxide and component produced therewith based on organic electronics

(76) Inventors: Dana Berlinde Habich, Erlangen (DE); Marcus Halik, Erlangen (DE); Oliver Hayden, Herzogenaurach (DE); Günter Schmid, Hemhofen (DE)

(21) Appl. No.: 13/138,563

(22) PCT Filed: Mar. 3, 2010
(86) PCT No.: PCT/EP2010/052700

§ 371 Date: Sep. 6, 2011

(30) Foreign Application Priority Data
Mar. 6, 2009 (DE) 10 2009 012 163.3

(51) Int. Cl. H01L 51/50; B05D 5/12; C23C 16/30

(52) U.S. Cl. 428/447; 427/58; 427/108

(57) ABSTRACT

Monolayers of organic compounds are formed on transparent conductive metal oxide surfaces these are used for example in producing organically based electronic components. By selecting the monolayer, the service life of the devices produced therewith may be improved by orders of magnitude.

### CROSS REFERENCE TO RELATED APPLICATIONS

This application is based on and hereby claims priority to International Application No. PCT/EP2010/052700 filed on Mar. 3, 2010 and German Application No. 10 2009 012 163.3 filed on Mar. 6, 2009, the contents of which are hereby incorporated by reference.

### BACKGROUND

The invention relates to a novel selection for monolayers of organic dielectric compounds particularly on transparent conductive metal oxide surfaces or oxide-containing metal surfaces, as used, for example, in the production of organic-based electronic components.

For the purposes of market introduction of OLEDs (organic light-emitting diodes) and/or OLEECs (organic light-emitting electrochemical cells), it is particularly advantageous to use monolayers with precisely adjusted functionality in electronic components to increase the lifetime, especially also in organic electronic components. In order that molecules in monolayers self-assemble and thus exhibit very high functionality and functional density, it is advisable to fix them to the particular electrodes by head or anchor groups, which results in automatic alignment of the linker groups, i.e. of the groups connecting the two ends. The attachment to the substrate takes place spontaneously provided that the substrate has been prepared appropriately.

The specific functionality is determined by the linkers and head groups. The anchor determines the self-assembly.

For this purpose, a known example from DE 10 2004 005 082 is an aromatic head group with π-π interaction, the introduction of which is chemically complex, and which binds a self-assembly dielectric layer to an electrode. The binding to the counterelectrode, the so-called anchor group of the organic dielectric compound which is usable as a monolayer in a capacitor, according to DE 10 2004 005 082 is a silane compound which can be bound to the electrode via an oxide layer formed from a non-copper oxide.

Asha Sharma, Bernard Kippelen, Peter J. Hotchkiss, and Seth R. Marder, “Stabilization of the work function of indium tin oxide using organic surface modifiers in organic light-emitting diodes”, Applied Physics Letters 93 (2008) 163308, discloses that it is possible using phosphonic acids to produce highly fluorinated SAM monolayers from the liquid phase.

It is demonstrated therein that at least partly fluorinated compounds exert a stabilizing effect on the ITO interface. For example, the stabilizing effect of specific SAM molecules for the increase in lifetime in efficient organic light-emitting diodes is also demonstrated graphically therein.

A disadvantage of the known related art is that the electrode surface, to apply the self-assembly monolayer (SAM), is preferably either functionalized or at least a considerable material excess from the liquid phase is employed, in order to achieve the desired effectiveness.

### SUMMARY

It is therefore one possible object to overcome the disadvantages of the related art and to provide a layer of SAM molecules which likewise increases the lifetime of the organic electronic light-emitting cells, preferably self-emitting components, but which is producible with small amounts on the electrode.

The inventors propose for the use of fluorinated silanes on transparent conductive metal oxide surfaces or oxide-containing metal surfaces, wherein the binding to the metal oxide surface is via the silane group. The invention also provides a process for producing a monolayer on a transparent conductive metal oxide layer, wherein a fluorinated straight-chain silane compound which binds to the metal oxide layer by the silane end is deposited from the gas phase. Finally, the invention provides an SAM layer produced from fluorinated silanes on a transparent conductive metal oxide layer, wherein the silanes are bound to the metal oxide surface from the gas phase.

The general finding of the invention is that not only ITO surfaces but also quite generally transparent conductive metal oxide (TCO) surfaces can be optimized by fluorinated compounds. An additional finding of the invention is that silanes can be used to bind these fluorinated compounds to the surfaces in an inexpensive manner. In contrast to the known compounds which anchor via phosphorus, the silanes can also be deposited without a liquid phase, which is both material-gentle (most depositions from liquids are performed by dip coating, by immersing the finished ITO layer) and material-saving.

The use of fluorinated silanes on dielectric surfaces is already tried and trusted, but it has always been assumed to date that the SAMs have an insulating effect on conductive surfaces and are therefore troublesome in the component. It has now been found that, surprisingly, the SAMs, which belong to the group of insulators, have good conductivities for charge carriers, especially for holes. The layer structure composed of TCO layer, SAM and hole conductor or electron injection layer, presented here for the first time leads to improved properties of the overall component in relation to energy efficiency, stability, etc., as has been shown here.

As shown experimentally, the material class of the fluorinated silanes has good adhesion to TCOs, especially ITO. These materials are commercially available and comparatively inexpensive (table 1). If relatively large containers are purchased, the costs can quite possibly be lowered by a factor of 10.

TABLE 1
Preferred materials for formation of the self-assembly monolayer according to
the present invention, which simultaneously increases hole injection and improves the lifetime of
the components.

| | Trichlorosilane | | | | |
|---|---|---|---|---|---|
| AB110562 | (3,3,3-Trifluor- | 10 g | 41.60 ε | [592-09-6] | C3H4Cl3F3Si |
| | opropyl)trichlorosilane; | | | | |
| | 97% | | | | |
| AB182091 | Nonafluorohexyltrichloro- | 10 g | 35.10 ε | [78560-47-1] | C6H4Cl3F9Si |
| | silane; 95% | | | | |
| AB111444 | (Tridecafluoro-1,1,2,2- | 10 g | 36.40 ε | [78560-45-9] | C8H4Cl3F13Si |
| | tetrahydrooctyl)trichlorosilane; | | | | |
| | 97% | | | | |
| AB103609 | 1H,1H,2H,2H- | 5 g | 46.20 ε | [78560-44-8] | C10H4Cl3F17Si |
| | Perfluorodecyltrichloro- | | | | |
| | silane; 97% | | | | |
| AB231951 | 1H,1H,2H,2H- | 1 g | 64.80 ε | [102488-50-6] | C14H4Cl3F25Si |
| | Perfluorotetrade- | | | | |
| | cyltrichlorosilane; 97% | | | | |
| | Ethoxysilane | | | | |
| AB252596 | Nonafluorohexyltriethoxysilane | 25 g | 72.80 ε | [102390-98-7] | C12H19F9O3Si |
| AB104055 | 1H,1H,2H,2H- | 5 g | 45.20 ε | [51851-37-7] | C14H19F13O3Si |
| | Perfluorooctyltriethoxysilane; | | | | |
| | 97% | | | | |
| AB172273 | 1H,1H,2H,2H- | 5 g | 46.00 ε | [101947-16-4] | C16H19F17O3Si |
| | Perfluorodecyltriethoxy- | | | | |
| | silane; 97% | | | | |
| | Methoxysilane | | | | |
| AB111473 | (3,3,3- | 5 g | 24.70 ε | [429-60-7] | C6H13F3O3Si |
| | Trifluoropropyl)trimethoxysilane; | | | | |
| | 97% | | | | |
| AB153265 | (Tridecafluoro-1,1,2,2,- | 10 g | 48.10 ε | [85857-16-5] | C11H13F13O3Si |
| | tetrahydrooctyl)trimethoxysilane; | | | | |
| | 95% packaged over copper | | | | |
| | powder | | | | |
| AB153340 | (Heptadecafluoro- | 5 g | 54.60 ε | [83048-65-1] | C13H13F17O3Si |
| | 1,1,2,2- | | | | |
| | tetrahydrodecyl)trimethoxysilane; | | | | |
| | 95% | | | | |

These have the general formula 1:

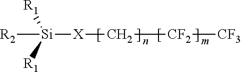

where R₁ and R₂ are each independently Cl or alkoxy, especially methoxy, ethoxy or OH.

X may be O, S, NH or absent; n is in the range from 0 to 5 and is preferably 0; m is from 0 to 20, especially from 5 to 10.

Formula 1 can be extended as shown below, such that ether units are between the individual constituents of the molecule chain; more particularly, h and f would then preferably be 2 or are generally between 1 and 4; X₁, X₂ and X₃ may each independently be O, S, NH, a halogen (F) or even absent; n is in the range from 0 to 2 and is preferably 0; m is from 0 to 15, especially between 2 and 5. The CF₃ group at the end of the molecule chain can also be omitted. In this case. X₃═F.

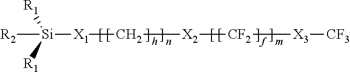

These compounds are preferably processed from the gas phase in a material-saving manner, which in the simplest case requires merely a temperature-controlled vacuum chamber. The substrates are preferably not activated by an RIE treatment with oxygen with sputtering properties, since saturation of the crystal lattice with oxygen should be avoided. A corresponding gentle treatment is intended to remove only organic impurities. It is usually sufficient to clean with common solvents (water, alcohols such as ethanol or organic solvents: NMP, dimethylformamide, dimethyl sulfoxide, toluene, chlorinated solvents such as chloroform, chlorobenzene, dichloromethane, ethers such as diethyl ether, tetrahydrofuran, dioxane, or esters such as ethyl acetate, methoxypropyl acetate, etc.). One option is an argon back-sputtering operation. The TCO—OSi bond is so strong that it even undermines minor soiling in the sub-monolayer region. This soiling can optionally be rinsed off with the solvents mentioned after the deposition. The processing of the SAM without solvating solvents gives very stable monolayers with good adhesion.

The following processes not specified in a restrictive manner are possible:
a. In batch processes which allow high parallelism. Subsequent handling of the substrates under air does not damage the coating.
b. In production plants there are back-sputtering units which can be used to apply the silanes from the gas phase after the cleaning.
c. All CVD (Chemical Vapor Deposition) and ALD (Atomic Layer Deposition) systems.

A preference for deposition from the gas phase does not rule out deposition from liquid phase. The highly reactive silanes, however, then have to be processed preferably from dried aprotic solvents. Since these are hygroscopic, the solutions do not have prolonged stability under air.

Within the context of the invention are not only transparent conductive electrodes based on indium tin oxide, but also other conductive electrodes, for example aluminum-doped zinc oxide. In the case of inverted diodes, the anode may also be formed of nontransparent metals with a native oxide surface. Examples here would be titanium, aluminum, nickel, etc.

The monolayer according to the invention is followed, in the stack structure of the organic electronic component, for example of the OLED or of the OLEEC, by a hole conductor layer.

For the hole conductor layer, the following materials are mentioned by way of example but in a nonrestrictive manner:
N,N′-bis(naphthalen-1-yl)-N,N′-bis(phenyl)-9,9-dimethylfluorene
N,N′-bis(3-methylphenyl)-N,N′-bis(phenyl)-9,9-diphenylfluorene
N,N′-bis(naphthalen-1-yl)-N,N′-bis(phenyl)-9,9-diphenylfluorene
N,N′-bis(naphthalen-1-yl)-N,N′-bis(phenyl)-2,2-dimethylbenzidine
N,N′-bis(3-methylphenyl)-N,N′-bis(phenyl)-9,9-spirobifluorene
2,2′,7,7′-tetrakis(N,N-diphenylamino)-9,9′-spirobifluorene
N,N′-bis(naphthalen-1-yl)-N,N′-bis(phenyl)benzidine
N,N′-bis(naphthalen-2-yl)-N,N′-bis(phenyl)benzidine
N,N′-bis(3-methylphenyl)-N,N′-bis(phenyl)benzidine
N,N′-bis(3-methylphenyl)-N,N′-bis(phenyl)-9,9-dimethylfluorene
N,N′-bis(naphthalen-1-yl)-N,N′-bis(phenyl)-9,9-spirobifluorene
Di-cyclohexane
2,2′,7,7′-tetra(N,N-ditolyl)aminospirobifluorene
9,9-bis-9H-fluorene
2,2′,7,7′-tetrakis-9,9-spirobifluorene
2,7-bis-9,9-spirobifluorene
2,2′-bis-9,9-spirobifluorene
N,N′-bis(phenanthren-9-yl)-N,N′-bis(phenyl)benzidine
N,N,N′,N′-tetranaphthalen-2-ylbenzidine
2,2′-bis(N,N-diphenylamino)-9,9-spirobifluorene
9,9-bis-9H-fluorene
9,9-bis-9H-fluorene
Titanium oxide phthalocyanine
Copper phthalocyanine
2,3,5,6-tetrafluoro-7,7,8,8-tetracyanoquinodimethane
4,4′,4″-tris(N-3-methylphenyl-N-phenylamino)triphenylamine
4,4′,4″-tris(N-(2-naphthyl)-N-phenylamino)triphenylamine
4,4′,4″-tris(N-(1-naphthyl)-N-phenylamino)triphenylamine
4,4′,4″-tris(N,N-diphenylamino)triphenylamine
Pyrazino phenanthroline-2,3-dicarbonitrile
N,N,N′,N′-tetrakis(4-methoxyphenyl)benzidine
2,7-bis-9,9-spirobifluorene
2,2′-bis-9,9-spirobifluorene
N,N′-di(naphthalen-2-yl)-N,N′-diphenylbenzene-1,4-diamine
N,N′-diphenyl-N,N′-di-benzidine
N,N′-diphenyl-N,N′-di-benzidine
Tri(diphenylbenzimidazoyl)iridium(III) DPBIC.

These hole transport layers may be doped or undoped. The dopants used are strong acceptors, such as copper salts, F4-TCNQs (tetrafluorotetracyanoquinodimethanes) or derivatives thereof. Likewise suitable are oxides such as molybdenum oxides, tungsten oxides or rhenium oxides.

It has been demonstrated experimentally that the cause of the initial decline in lifetime in an organic light-emitting diode is the degradation of the interface between the oxygen-laden indium tin oxide electrode and the hole transport material. It is exactly here that the improvement achieved by the present invention intervenes, since the surprising conductivity of the SAM layer for holes eliminates this interface of the TCO with the hole conductor layer without impairing the performance of the component.

The oxygen loading serves to adjust the work function of the anode. Compared to the related art, the proposed self-assembly monolayers offer the following advantages:
high work functions without RIE pretreatment
inexpensive materials
processing from the gas phase
increase in the lifetime of the organic component and complete avoidance of the initial decline in lifetime in luminance and voltage rise and power efficiency.

In contrast to the related art, all advantages are fulfilled at the same time here. As shown in the examples, the selection of possible molecule classes is very limited. A variation in the anchor groups was also studied. The silane anchor group used here appears to be ideal for the use of indium tin oxide surfaces.

### EXAMPLE 1

### Pretreatment of the ITO Anode

The reference used is the standard pretreatment. For this purpose, a glass plate coated with 150 nm of indium tin oxide is exposed to an oxygen plasma for 10 min. The plasma with a 500 W HF output at an oxygen pressure of 0.6 mbar burns directly over the substrate. The characteristics of a diode whose substrate has been treated in such a way are shown in red in graphs below. This pretreatment is necessary in order that the proposed diode and the reference diode have approximately the same performance data in order to be able to better compare them with one another.

### EXAMPLE 2

A substrate analogously to example 1 is exposed in a reactor with a two-chamber system to a gentle cleaning step at 250 W HF power for 10 min. The plasma burns in one chamber and the substrate is in the second chamber not flooded with plasma. The pressure in the substrate chamber is 0.5 mbar. In this way, it is possible to very gently remove organic impurities. Sputtering effects and incorporation of oxygen into the crystal lattice do not occur. Normally, such a pretreatment is insufficient for efficient organic light-emitting diodes. Thereafter, a self-assembly monolayer containing the perfluorodecyltrichlorosilane reagent was deposited.

For this purpose, a commercial system for molecular vapor deposition was used, which is already used globally in companies and research centers, the MVD100 system from Applied MST (http://www.appliedmst.com/products mvd100.htm pdf “Overview” and “Features”). This is formed from a vacuum chamber in which the substrates can be positioned, which is connected to a second chamber in which the oxygen plasma is ignited. This means that the ions are not accelerated directly onto the substrate. The duration, HF power and gas flow rate can be varied. Three gas feed lines are used to pass the substances to be deposited and a catalyst, in this case water vapor, into the main chamber. In three preliminary chambers, the necessary pressure can be generated and the necessary temperature can be established in order to convert the substances to the gas phase. For the deposition of one layer of perfluoro-, decyl-, trichlorosilane, a chamber pressure of 0.6 mbar is established. The reaction time is 900 sec. Subsequently, at 8 mbar, water vapor is used to catalyze the binding and crosslinking. This method of deposition does not require any further aftertreatment; the diode can be applied directly to the SAM substrate.

The characteristic for a diode which has been assembled on this substrate is shown in black.

### EXAMPLE 3

A long-known diode includes NPB hole conductor (N,N′-bis(naphthalen-2-yl)-N,N′-bis(phenyl)benzidine) and the electron conductor Alq (tris(8-hydroxyquinolinolato)aluminum). For this purpose, 40 nm of NBP and 40 nm of Alq are deposited from the gas phase. The cathode is formed by a layer of 0.7 nm of lithium fluoride and 200 nm of aluminum.

The SAM layer of fluorinated silanes on the conductive metal oxide layer connects this layer to a hole conduction or electron injection layer without formation of a direct interface between these layers. This allows all faults which arise from the formation of these interfaces to be avoided.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows the luminance (right-hand axis) and the current characteristic (left-hand axis) of two identically produced NPB-Alq OLEDs or corresponding OLEECs;

FIG. 2 shows the voltage curve of an NPB-Alq diode in prolonged operation under constant current;

FIG. 3 shows the decline in luminance of both components with increased operating time at constant current; and

FIG. 4 shows the power efficiency of the OLEDs compared over a prolonged period.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

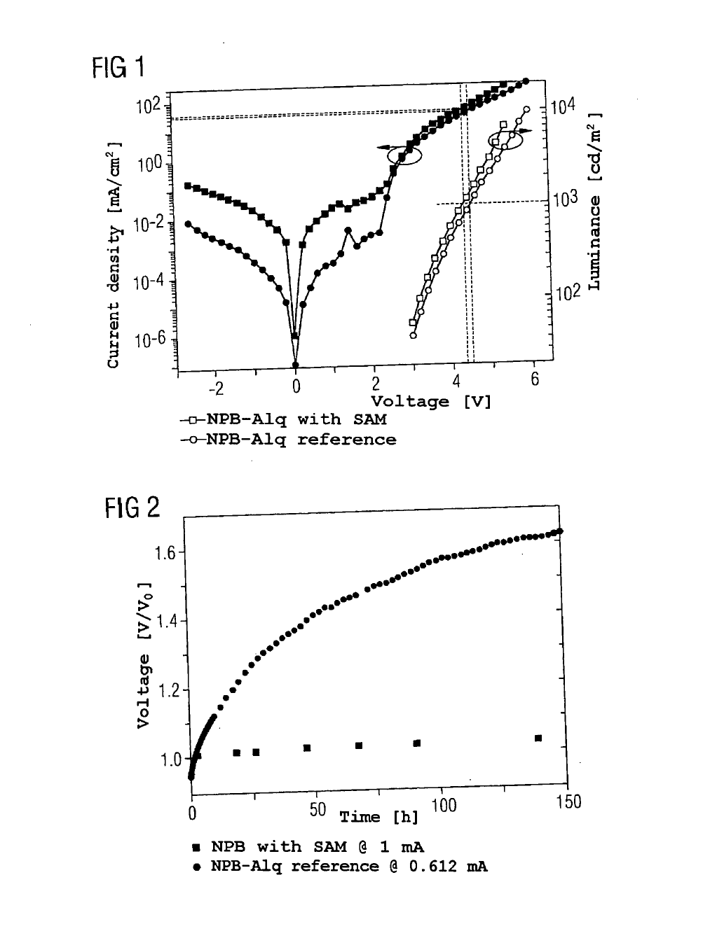

FIG. 1 shows the luminance (right-hand axis) and the current characteristic (left-hand axis) of two identically produced NPB-Alq OLEDs or corresponding OLEECs. The difference lies merely in the pretreatment of the TCO, here an ITO layer, with red (round) showing the layer treated conventionally with oxygen plasma and black (square) the layer pretreated with perfluorodecyltrichloro-, silane.

The I-V and luminance characteristic of the diodes with substrates from examples 1 and 2 are shown in FIG. 1.

The dark currents of the diode with an SAM-coated substrate are somewhat higher compared to the reference diode. In the passage range, the two organic light-emitting diodes are virtually identical.

FIG. 2 shows the voltage curve of an NPB-Alq diode in prolonged operation under constant current. It is evident here in a quite dramatic manner how the lifetime of the line shown by black squares at the bottom for the ITO layer treated has increased.

Under the conditions specified in FIG. 2, the diodes were operated at constant current for 150 hours. The constant current is guided by both diodes glowing with equal brightness with luminance in the same order of magnitude. The reference diode had an initial luminance of 1000 cd/m2, the SAM diode an initial luminance of 670 cd/m2. While the voltage in the reference diode rises by more than 60% in order to maintain the constant current, the voltage remains virtually constant in the component in spite of higher total charge flow.

FIG. 3 shows the decline in luminance of both components with increased operating time at constant current.

In the reference OLED (again red and round, the curve falling steeply even at the start), a significant collapse in luminance of approx. 10% is observed at the start, which is attributable to the degradation of the anode-hole conductor interface. Thereafter, the component stabilizes and the “normal” degradation process of the emitter becomes visible. In the case of the OLED (the comparative test could also be conducted with a corresponding OLEEC structure), the initial decline in luminance is not observed. The somewhat steeper decline after prolonged operating time results from the higher current loading overall. As a result of the ITO pretreatment with the self-assembly monolayer deposited from the gas phase, the luminous efficiency of the diode is maintained for much longer, which significantly prolongs the LT70 lifetime (LT70: decline in the starting luminance to 70%).

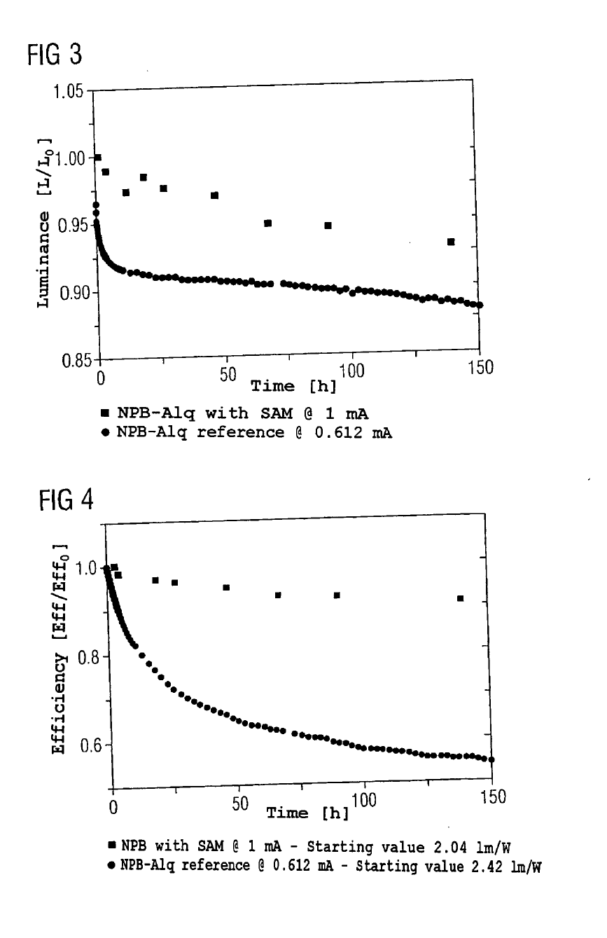

FIG. 4 shows the power efficiency of the OLEDs compared over a prolonged period. Here too, the OLED shines again, where a record value comparable to the untreated OLED at the start is maintained virtually over the entire measurement period.

The selection of functioning molecules for the SAM with positive effects on lifetime and efficiency is very limited, as has been demonstrated impressively in the literature and in in-house tests:

For instance, it has been demonstrated that, instead of trichlorosilane, for example, it also possible to use trimethoxysilane.

The proposals relate to a novel selection for monolayers of organic dielectric compounds on transparent conductive metal oxide surfaces, as used, for example, in the production of organic-based electronic components. The selection achieves completely new orders of magnitude in lifetime of the devices thus produced. Furthermore, it is also possible to mention many advantageous fields of use of these monolayers, for example use for corrosion protection, for lithography, etc.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-13. (canceled)

14. A method of forming a monolayer on a metal surface, comprising:
providing a metal having a conductive metal oxide surface;
providing an organic compound having a fluorinated silane group; and
binding the organic compound to the conductive metal oxide surface via the silane group.

15. The method as claimed in claim 14, wherein the conductive metal oxide surface is transparent.

16. The method as claimed in claim 14, wherein the organic compound is represented by the following formula: 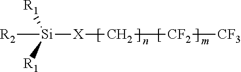
where R₁, R₂, R₃ are each independently selected to be Cl, an alkoxy, or OH,
X is O, S, NH or absent,
n is from 0 to 5, and
m is from 0 to 20.

17. The method as claimed in claim 14, wherein the organic compound is represented by the following formula: 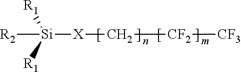
where R₁, R₂, R₃ are each independently selected to be Cl, a methoxy, an ethoxy or OH,
X is O, S, NH or absent,
n is 0, and
m is from 5 to 10.

18. The method as claimed in claim 14, wherein the organic compound is represented by the following formula: 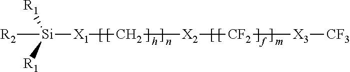
where h and f each independently have a value from 1 to 4,
X₁, X₂ and X₃ are each independently selected to be 0, S, a halogen, NH or absent,
n is from 0 to 2, and
m is from 0 to 15.

19. The method as claimed in claim 14, wherein
the organic compound is a fluorinated straight-chain silane compound having a silane end, and
the organic compound is deposited in the gas phase to cause the silane end to bond to the metal oxide surface.

20. The method as claimed in claim 19, wherein gas phase deposition is performed in a temperature-controllable vacuum chamber.

21. The method as claimed in claim 19, wherein the organic compound is deposited using Chemical Vapor Deposition (CVD) and/or Atomic Layer Deposition (ALD).

22. A product comprising:
a conductive metal oxide layer;
self-assembly monolayer (SAM) formed from a fluorinated silane bonded to the conductive metal oxide layer; and
a hole conduction or electron injection layer conductively connected to the conductive metal oxide layer via the SAM layer without formation of a direct interface between the metal oxide layer and the hole conduction or electron injection layer.

23. The product as claimed in claim 22 wherein the silane is selected from trichlorosilanes, ethoxysilanes and methoxysilanes.

24. The product as claimed in claim 22, wherein the organic compound is represented by the following formula: 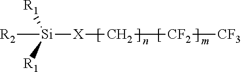
where R₁, R₂, R₃ are each independently selected to be Cl, or alkoxy, and OH,
X is O, S, NH or absent,
n is from 0 to 5, and
m is from 0 to 20.

25. The product as claimed in claim 22, wherein the organic compound is represented by the following formula: 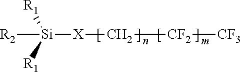
where R₁, R₂, R₃ are each independently selected to be Cl, a methoxy, an ethoxy or OH,
X is O, S, NH or absent,
n is 0, and
m is from 5 to 10.

26. The product as claimed in claim 22, wherein the organic compound is represented by the following formula: 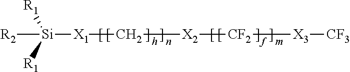
where h and f each independently have a value from 1 to 4,
X₁, X₂ and X₃ are each independently selected to be O, S, a halogen, NH or absent,
n is from 0 to 2, and
m is from 0 to 15.

27. A product comprising:
a conductive metal oxide layer; and
self-assembly monolayer (SAM) formed from a fluorinated silane bonded to the conductive metal oxide layer, wherein the silane is bound on a surface of the metal oxide layer from the gas phase.

28. The product as claimed in claim 27 wherein the silane is selected from trichlorosilanes, ethoxysilanes and methoxysilanes.

29. The product as claimed in claim 27, wherein the organic compound is represented by the following formula: 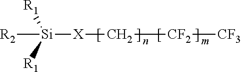
where R₁, R₂, R₃ are each independently selected to be Cl, or alkoxy, and OH,
X is O, S, NH or absent,
n is from 0 to 5, and
m is from 0 to 20.

30. The product as claimed in claim 27, wherein the organic compound is represented by the following formula: 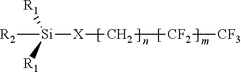
where R₁, R₂, R₃ are each independently selected to be Cl, a methoxy, an ethoxy or OH,
X is O, S, NH or absent,
n is 0, and
m is from 5 to 10.

31. The product as claimed in claim 27, wherein the organic compound is represented by the following formula: 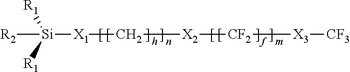
where h and f each independently have a value from 1 to 4,
X₁, X₂ and X₃ are each independently selected to be O, S, a halogen, NH or absent,
n is from 0 to 2, and
m is from 0 to 15.

32. A product comprising:
a transparent conductive metal oxide surface;
self-assembly monolayer (SAM) on the transparent conductive metal oxide surface, the self-assembly monolayer having a head group and an anchor group, the anchor group being attached to the oxide surface;
a layer formed from a hole-conducting compound attached to the head group of the self-assembly monolayer, the hole-conducting compound being selected from the group consisting of:
N,N′-bis(naphthalen-1-yl)-N,N′-bis(phenyl)-9,9-dimethylfluorene,
N,N′-bis(3-methylphenyl)-N,N′-bis(phenyl)-9,9-diphenylfluorene,
N,N′-bis(naphthalen-1-yl)-N,N′-bis(phenyl)-9,9-diphenylfluorene,
N,N′-bis(naphthalen-1-yl)-N,N′-bis(phenyl)-2,2-dimethylbenzidine,
N,N′-bis(3-methylphenyl)-N,N′-bis(phenyl)-9,9-spirobifluorene,
2,2′,7,7′-tetrakis(N,N-diphenylamino)-9,9′-spirobifluorene,
N,N′-bis(naphthalen-1-yl)-N,N′-bis(phenyl)benzidine,
N,N′-bis(naphthalen-2-yl)-N,N′-bis(phenyl)benzidine,
N,N′-bis(3-methylphenyl)-N,N′-bis(phenyl)benzidine,
N,N′-bis(3-methylphenyl)-N,N′-bis(phenyl)-9,9-dimethylfluorene,
N,N′-bis(naphthalen-1-yl)-N,N′-bis(phenyl)-9,9-spirobifluorene,
Di-cyclohexane,
2,2′,7,7′-tetra(N,N-ditolyl)aminospirobifluorene,
9,9-bis-9H-fluorene,
2,2′,7,7′-tetrakis-9,9-spirobifluorene,
2,7-bis-9,9-spirobifluorene,
2,2′-bis-9,9-spirobifluorene,
N,N′-bis(phenanthren-9-yl)-N,N′-bis(phenyl)benzidine,
N,N,N′,N′-tetranaphthalen-2-ylbenzidine,
2,2′-bis(N,N-diphenylamino)-9,9-spirobifluorene,
9,9-bis-9H-fluorene,
9,9-bis-9H-fluorene,
Titanium oxide phthalocyanine,
Copper phthalocyanine,
2,3,5,6-tetrafluoro-7,7,8,8-tetracyanoquinodimethane,
4,4′,4″-tris(N-3-methylphenyl-N-phenylamino)triphenylamine,
4,4′,4″-tris(N-(2-naphthyl)-N-phenylamino)triphenylamine,
4,4′,4″-tris(N-(1-naphthyl)-N-phenylamino)triphenylamine,
4,4′,4″-tris(N,N-diphenylamino)triphenylamine,
Pyrazino phenanthroline-2,3-dicarbonitrile,
N,N,N′,N′-tetrakis(4-methoxyphenyl)benzidine,
2,7-bis-9,9-spirobifluorene,
2,2′-bis-9,9-spirobifluorene,
N,N′-di(naphthalen-2-yl)-N,N′-diphenylbenzene-1,4-diamine,
N,N′-diphenyl-N,N′-di-benzidine,
N,N′-diphenyl-N,N′-di-benzidine, and
Tri(diphenylbenzimidazoyl)iridium(III) DPBIC.

33. The product as claimed in claim 32, wherein the self-assembly monolayer functions as an organic electronic component.

34. The product as claimed in claim 32, wherein the self-assembly monolayer functions as an organic light-emitting diode or an organic light-emitting electrochemical cell (OLEEC).
